(19) United States
(12) Patent Application Publication
(10) Pub. No.: US 2014/0004652 A1
(43) Pub. Date: Jan. 2, 2014

(54) METHOD OF FABRICATING SOLAR CELL

(71) Applicant: AU Optronics Corp., Hsin-Chu (TW)

(72) Inventors: Ming-Jeng Huang, Hsin-Chu (TW); Wen-Chin Lo, Hsin-Chu (TW); Chin-Tien Yang, Hsin-Chu (TW)

(21) Appl. No.: 13/918,995

(22) Filed: Jun. 17, 2013

(30) Foreign Application Priority Data
Jun. 27, 2012 (CN) 201210217327.5

(51) Int. Cl. H01L 31/18

(52) U.S. Cl. CPC H01L 31/18
USPC 438/87

(57) ABSTRACT

A method of fabricating solar cell uses simplified processes to form a lightly-doped region having a textured surface and a heavily-doped region having a flat surface. A flat interface is formed between the heavily-doped region and an electrode, which has a relative lower contact resistance.

### BACKGROUND OF THE DISCLOSURE

1. Field of the Disclosure

The present disclosure relates to a method of fabricating a solar cell, and more particularly, a method for fabricating the solar cell using simplified processes, wherein a lightly-doped region with a texture surface and a heavily-doped region with a flat surface are formed at the same time.

2. Description of the Prior Art

As our natural resources are limited and set to decline rapidly, the demand for alternatives to present energy has grown dramatically in recent years. Among all kinds of alternative energy, solar energy is with the most potential from an environmental perspective because it is an inexhaustible source of energy as long as the sun is there.

Due to its high production cost, complicated process, and low photo-electric conversion efficiency, there are still many obstacles waiting to be overcome in the development of solar cell technology. Therefore, fabricating solar cells with low production cost, simple process, and high conversion efficiency to replace the conventional high-pollution and high-risk energy is a main objective in the field.

To raise the photo-electric conversion efficiency, currently, a solar cell with a selective emitter is developed in industry. Please refer to FIG. 1. FIG. 1 is a schematic diagram illustrating a conventional solar cell. As shown in FIG. 1, the conventional solar cell includes a substrate 2, a lightly-doped region 3, a heavily-doped region 4, a first electrode 5, an anti-reflection layer 6, a back surface field (BSF) structure 7, and a second electrode 8. The substrate 2 has a first surface 21 and a second surface 22. To increase the incident light intensity, the first surface 21 of the substrate 2 has a texture surface. The lightly-doped region 3 and the heavily-doped region 4 are formed adjacent to the first surface 21 of the substrate 2. The first electrode 5 is disposed on the heavily-doped region 4. The anti-reflection layer 6 is disposed on the lightly-doped region 3. The BSF structure 7 and the second electrode 8 are disposed on the second surface 22 of the substrate 2.

Because the heavily-doped region 4 and the first electrode 5 have lower contact resistance, the photo-electric conversion efficiency of the solar cell 1 may be enhanced theoretically. However, due to the texture surface in the heavily-doped region 4 of the conventional solar cell 1, the contact resistance between the first electrode 5 and the heavily-doped region 4 do not decrease as expected despite the fact that the first electrode 5 is in contact with the heavily-doped region 4; this has an influence on the photo-electric conversion efficiency of the solar cell. Moreover, the texture surface of the first surface 21 on the substrate 2 of the conventional solar cell 1 is formed with a wet etching process, so the texture surface of the first surface 21, in this condition, has a higher reflection rate, preventing the incident light intensity from increasing.

### SUMMARY OF THE DISCLOSURE

It is one of the objectives of the disclosure to provide a method of fabricating a solar cell, thereby boosting the conversion efficiency.

To achieve the purposes described above, an embodiment of the disclosure provides a method of fabricating the solar cell. The method includes the following steps. First, a substrate having a first surface and a second surface opposite to the first substrate is provided. And then, a diffusion process is carried out to diffuse a dopant into the substrate to form a first doped region adjacent to the first surface. The first doped region has a first doped type. A patterned mask layer is formed on the first doped region. The patterned mask layer shields a portion of the first doped region and exposes the other portion of the first doped region. The portion of the first doped region exposed by the patterned mask layer and a portion of the dopant in the first doped region exposed by the patterned mask layer is partially removed to make the first doped region exposed by the patterned mask layer as a lightly-doped region, which has a textured surface. The patterned mask layer is removed to expose the first doped region shielded by the patterned mask layer; the first doped region shielded by the patterned mask layer is formed a heavily-doped region and has a flat surface. A second doped region is formed on the substrate adjacent to the second surface; the second doped region has a second doped type, which is opposite to the first doped type. A first electrode is formed on the heavily-doped region in the first surface of the substrate.

The present method of fabricating the solar cell of the disclosure only requires one single process to form the lightly-doped region with the texture surface and the heavily-doped region with the flat surface at the same time, and thus has the advantage of process simplification and low cost. Moreover, the interface between the heavily-doped region and the first electrode is flat; therefore, it has lower contact resistance which could raise the conversion efficiency of the solar cell.

These and other objectives of the present disclosure will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute a part of this specification. The drawings illustrate some of the embodiments and, together with the description, serve to explain their principles. In the drawings:

FIG. 1 is a schematic diagram illustrating a conventional solar cell.

FIGS. 2-7 are schematic diagrams illustrating a method of fabricating a solar cell according to a first embodiment of this disclosure.

FIG. 8 is a schematic diagram illustrating a method of fabricating the solar cell according to a second embodiment of this disclosure.

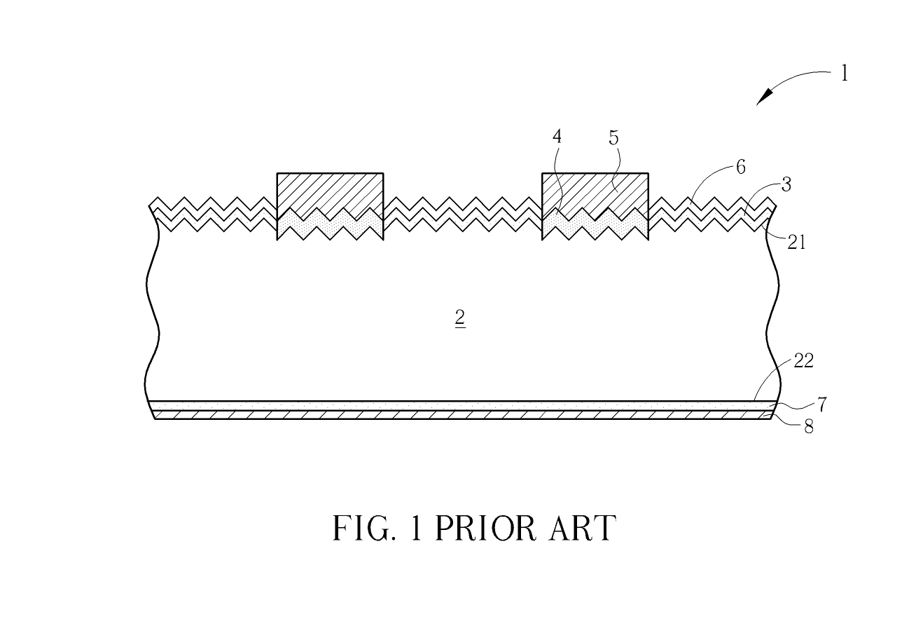

### DETAILED DESCRIPTION

To provide a better understanding of the present disclosure, the embodiments will be made in detail. The embodiments of the present disclosure are illustrated in the accompanying drawings with numbered elements. In addition, the terms such as “first” and “second” described in the present disclosure are used to distinguish different components or processes, which do not limit the sequence of the components or processes.

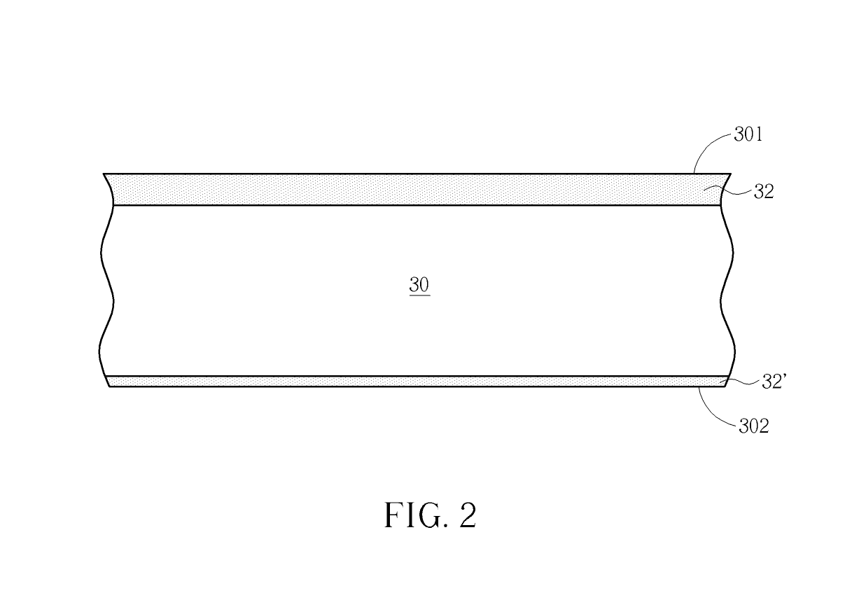

Please refer to FIGS. 2-7. FIGS. 2-7 are schematic diagrams illustrating a method of fabricating a solar cell according to a first embodiment of this disclosure. As shown in FIG. 2, a substrate 30 is provided first. The substrate 30 may be a silicon substrate, which is, for example, a single crystalline silicon substrate, a polycrystalline silicon substrate, a microcrystalline silicon substrate or a nanocrystalline silicon substrate, but not limited thereto. The substrate 30 may be any other kinds of semiconductor substrates. The substrate 30 has a first surface 301 and a second surface 302 that is opposite to the first surface 301, and the first surface 301 is the light incident plane. A saw damage removal (SDR) process is then performed on the substrate 30, which includes cleaning the substrate 30 with, for instance, acidic or alkaline solution to remove slight damage from the substrate 30. Then, a diffusion process is performed, which includes diffusing a dopant into the substrate 30 to form a first doped region 32 adjacent to the first surface 301 in high temperature. The first doped region 32 has a first doped type. The first doped type may be n-type, and in this condition the dopant may be phosphorous, arsenic, antimony, or compounds thereof. For example, if the dopant is phosphorous, phosphorous may be diffused into the substrate 30 to form the first doped region 32 on the substrate 30 adjacent to the first surface 301 in the diffusion process. If the second surface 302 of the substrate 30 is not shielded, phosphorous may also be diffused into the substrate 30 to form another first doped region 32′ in the substrate 30 adjacent to the second surface 302 in the diffusion process. Moreover, in the diffusion process, silicon of the substrate 30 may react with phosphorous to form phosphorosilicate glass (PSG) on the surface of the substrate 30 (figure not shown). The first doped type may be p-type, and in this condition the dopant may be, for instance, boron or boron compounds.

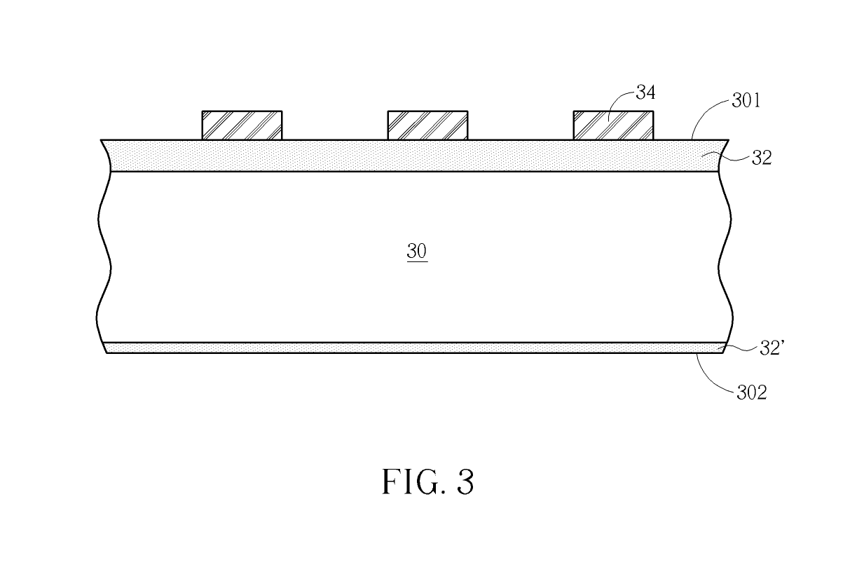

As shown in FIG. 3, a patterned mask layer 34 is formed on the first doped region 32. The patterned mask layer 34 shields a portion of the first doped region 32 and exposes the other portion of the first doped region 32. The first doped region 32 shielded by the patterned mask layer 34 is located where a heavily-doped region is to be formed later, and the first doped region 32 exposed by the patterned mask layer 34 is located where a lightly-doped region is to be formed. The patterned mask layer 34 can be formed on the first surface 301 of the substrate 30 by an ink-jet printing process, but not limited thereto.

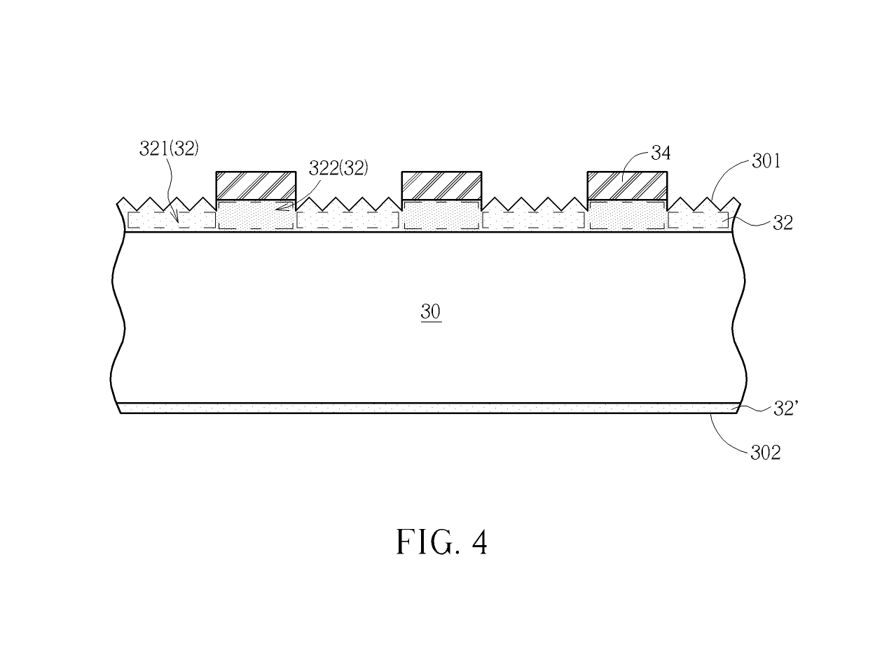

As shown in FIG. 4, the portion of the first doped region 32 exposed by the patterned mask layer 34 and a portion of the dopant in the first doped region 32 exposed by the patterned mask layer 34 are removed partially. Consequently, the first doped region 32 exposed by the patterned mask layer 34 forms a lightly-doped region 321 while the first doped region 32 shielded by the patterned mask layer 34 forms a heavily-doped region 322, because the doping concentration of the first doped region 32 shielded by the patterned mask layer 34 remains the same as the original. Moreover, after partially removing the portion of the first doped region 32 exposed by the patterned mask layer 34 and the portion of the dopant in the first doped region 32 exposed by the patterned mask layer 34, the lightly-doped region 321 has a textured surface, while the heavily-doped region 322 shield by the patterned mask layer 34 has a flat surface. The textured surface of the lightly-doped region 321 is formed by a plurality of micro-structures such as pyramid structures, and the height of each micro-structure is substantially 0.1 um-0.15 um, but not limited thereto. In this embodiment, the original doping concentration of the first doped region 32 is substantially in a range of 10¹⁹ atom/cm³ to 10²¹ atom/cm³. After partially removing the portion of the first doped region 32 exposed by the patterned mask layer 34 and the dopant in the first doped region 32 exposed by the patterned mask layer 34, the doping concentration of the first doped region 32 exposed by the patterned mask layer 34 is substantially in a range of 10¹⁸ atom/cm³ to 10¹⁹ atom/cm³ and the first doped region 32 exposed by the patterned mask layer 34 forms the lightly-doped region 321, because a portion of the dopant in the first doped region 32 exposed by the patterned mask layer 34 is removed; the doping concentration of the first doped region 32 shielded by the patterned mask layer 34 is substantially in a range of 10¹⁹ atom/cm³ to 10²¹ atom/cm³ and the first doped region 32 shielded by the patterned mask layer 34 forms the heavily-doped region 322. Furthermore, the sheet resistance of the lightly-doped region 321 is substantially in a range of 90 Ω/□ to 120 Ω/□ (90 ohm/square-120 ohm/square), and that of the heavily-doped region 322 is substantially in a range of 40 Ω/□ to 60 Ω/□ (40 ohm/square-60 ohm/square), but not limited thereto. In this embodiment, the step of partially removing the portion of the first doped region 32 exposed by the patterned mask layer 34 and a portion of the dopant in the first doped region 32 exposed by the patterned mask layer 34 to form the lightly-doped region 321 having the texture surface includes performing a dry etching process such as a reactive ion etching (RIE) process.

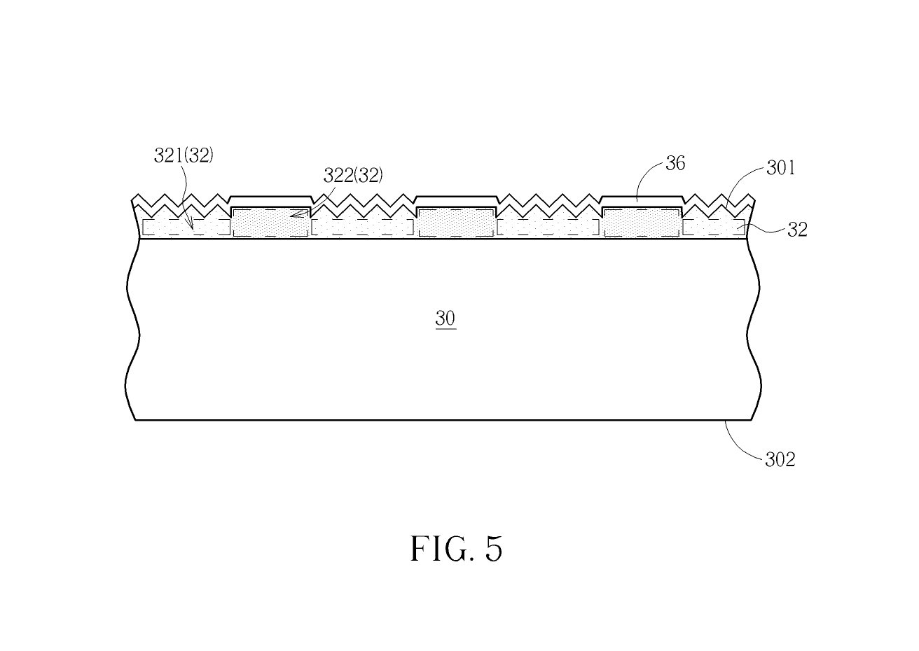

As shown in FIG. 5, the patterned mask layer 34 is removed. An edge isolation process is then carried out to remove the doped layer at the edge of the substrate 30 formed in the diffusion process for ensuring the first surface 301 and the second surface 302 of the substrate 30 are electrically isolated. The edge isolation process may be, for example, a laser cutting process, a dry etching process, or a wet etching process. Moreover, the phosphorosilicate glass formed by the diffusion process on the surface of the substrate 30 is removed with, for example, an acidic solution. After removing the patterned mask layer 34, another removal step is performed to remove the first doped region 32′ disposed adjacent to the second surface 302 of the substrate 30. And an anti-reflection layer 36 is formed on the first surface 301 of the substrate 30. The anti-reflection layer 36 is formed conformally on the first surface 301 of the substrate 30; therefore, the anti-reflection layer 36 in the lightly-doped region 321 has the texture surface, and the anti-reflection layer 36 in the heavily-doped region 322 has the flat surface. The anti-reflection layer 36 can increase the incident light intensity and raise the photo-electric conversion efficiency. The anti-reflection layer 36 may be a single-layered or multiple-layered structure, but not limited thereto. The material of the anti-reflection layer 36 may be silicon nitride, silicon oxide, silicon oxynitride, or other appropriate material, but not limited thereto. The anti-reflection layer 36 may be formed by a plasma-enhanced chemical vapor deposition (PECVD) process, for example, but not limited thereto.

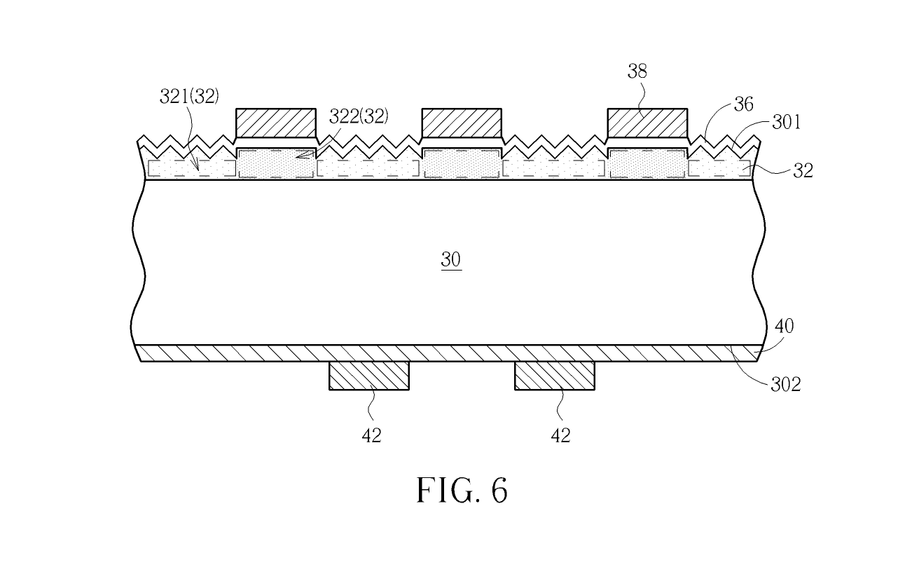

As shown in FIG. 6, a first electrode 38 is formed on the heavily-doped region 322 disposed in the first surface 301 of the substrate 30, a metallic layer 40 is formed on the second surface 302 of the substrate 30, and a second electrode 42 is formed on the metallic layer 40. The first electrode 38 may be a single-layered or multiple-layered structure, which serves as the finger electrode of the solar cell. The material of the first electrode 38 may be high conductivity material, such as silver (Ag), but not limited thereto. The material of the first electrode 38 may be other high conductivity material, such as gold (Au), aluminum (Al), copper (Cu), or stannum (Sn). The metallic layer 40 may be a flexible metal layer with a single-layered or multiple-layered structure. The material of the metallic layer 40 may be, for instance, lead (Pb), stannum (Sn), antimony (Sb), aluminum (Al) or alloy thereof. Preferably, the material of the metallic layer 40 may be aluminum or aluminum alloy, but not limited thereto. The second electrode 42 may be a single-layered or multiple-layered structure, which serves as the back electrode for the solar cell. The material of the second electrode 42 may be high conductivity material, such as silver (Ag), but not limited thereto. The material of the second electrode 42 may be other high conductivity material, such as gold (Au), aluminum (Al), copper (Cu), or stannum (Sn). The order in which the first electrode 38, the metallic layer 40, and the second electrode 42 are formed is not restricted. In this embodiment, the first electrode 38 and the second electrode 42 are preferably formed by printing processes individually. The material of the first electrode 38 and the second electrode 42 may be conductive paste, for instance, conductive paste with silver or aluminum, but not limited thereto.

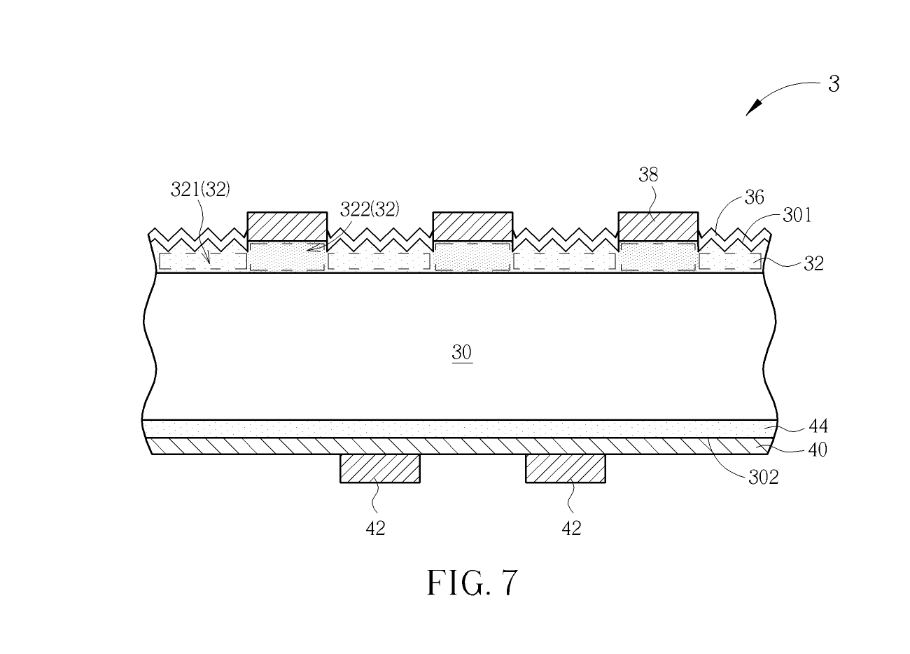

As shown in FIG. 7, a sintering process is performed to make the first electrode 38 penetrate through the anti-reflection layer 36, thereby contacting and electrically connecting the heavily-doped region 322. As the metallic layer 40 react with the substrate 30 to form metal silicide by the sintering process, a second doped region 44 is formed on the substrate 30 adjacent to the second surface 302. Accordingly, the solar cell 3 of this embodiment is completed. On the condition that the metallic layer 40 is made of aluminum or aluminum alloy, the second doped region 44 is made of aluminum silicide. The second doped region 44 is the back surface field structure for the solar cell 3, and has the second doped type; in other words, the doped type of the second doped region 44 is opposite to the doped type of the lightly-doped region 321 and the heavily-doped region 322. For example, if the lightly-doped region 321 and the heavily-doped region 322 are n-type, the second doped region 44 is p-type; on the contrary, if the lightly-doped region 321 and the heavily-doped region 322 are p-type, the second doped region 44 is n-type. The substrate 30 may be a doped substrate, and the doped type of the substrate 30 must be the second doped type, same as the second doped region 44.

Methods of fabricating the solar cell are not restricted to the preceding embodiments. Another feasible method of fabricating the solar cell will be disclosed in the following paragraphs. For brevity purposes, like or similar features in multiple embodiments will be described with similar reference numerals for ease of illustration and description thereof.

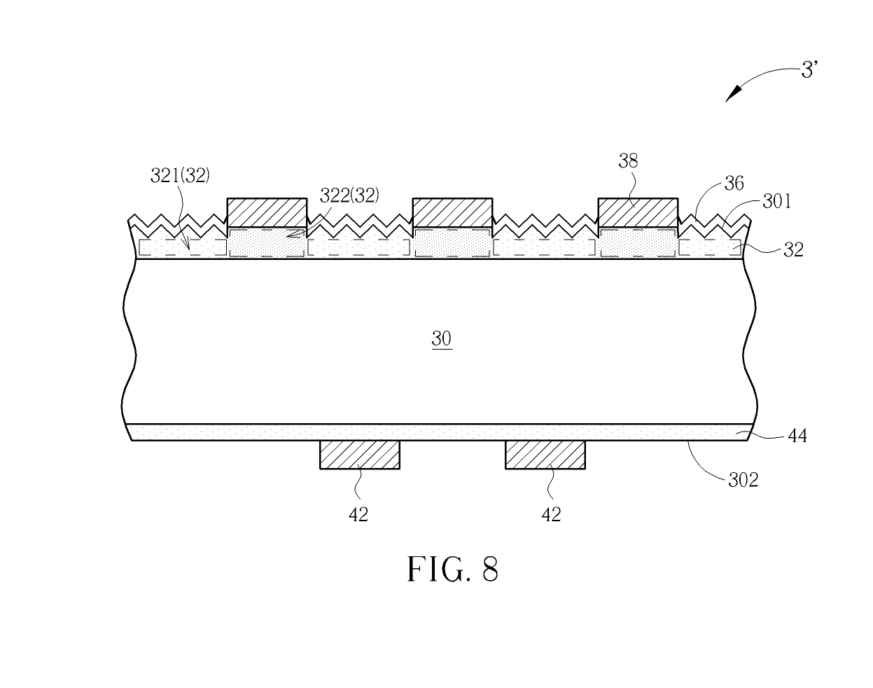

Please refer to FIG. 8 and FIGS. 2-5. FIG. 8 is a schematic diagram illustrating a method of fabricating the solar cell according to a second embodiment of this disclosure. The main difference between the method of fabricating the solar cell of this embodiment and that of the first embodiment is the method to form the second doped region. The method of fabricating the solar cell of this embodiment continues from the step of FIG. 5 of the first embodiment. As shown in FIG. 8, after the anti-reflection layer 36 is formed on the first surface 301 of the substrate 30, another diffusion process is carried out to diffuse the dopant into the substrate 30 to form the second doped region 44 adjacent to the second surface 302. The second doped region 44 has the second doped type. The second doped type may be n-type, and in this condition the dopant may be, for example, phosphorous, arsenic, antimony, or compounds thereof. In other words, the second doped type may be p-type, and in this condition the dopant may be, for example, boron or boron compounds. The first electrode 38 is formed on the heavily-doped region 322 in the first surface 301 of the substrate 30, and the second electrode 42 is formed on the second surface 302 of the substrate 30. Then, the sintering process is performed to make the first electrode 38 penetrate through the anti-reflection layer 36, thereby contacting and electrically connecting the heavily-doped region 322. Accordingly, the solar cell 3′ of this embodiment is completed. In this embodiment, the first electrode 38 and the second electrode 42 may be formed by a screen printing or an electroplating process, but not limited thereto.

To sum up, in the present disclosure, the lightly-doped region and the heavily-doped region are substantially in the same plane, and the height in the lightly-doped region is slightly lower than that in the heavily-doped region. The lightly-doped region has the texture surface to increase incident light intensity; the heavily-doped region has the flat surface to provide lower contact resistance for the selective emitter formed from the heavily-doped region and the first electrode, and can thus increase the conversion efficiency. Moreover, because both the lightly-doped region with the texture surface and the heavily-doped region with the flat surface are formed in the same dry etching process, the present disclosure has the advantage of process simplification and low cost. Comparing to the texture surface formed in a wet etching process, the texture surface formed in the dry etching process in the present disclosure has lower reflection rate, and thus further increase the incident light intensity.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A method of fabricating a solar cell, comprising:
providing a substrate having a first surface and a second surface opposite to the first surface;
performing a diffusion process to diffuse a dopant into the substrate to form a first doped region adjacent to the first surface, wherein the first doped region has a first doped type;
forming a patterned mask layer on the first doped region, wherein the patterned mask layer shields a portion of the first doped region and exposes the other portion of the first doped region;
partially removing the portion of the first doped region exposed by the patterned mask layer and a portion of the dopant in the first doped region exposed by the patterned mask layer to make the exposed portion of the first doped region as a lightly-doped region, wherein the lightly-doped region has a textured surface;
removing the patterned mask layer to expose the other portion of the first doped region, wherein the other portion of the first doped region is a heavily-doped region and has a flat surface;
forming a second doped region in the substrate adjacent to the second surface, wherein the second doped region has a second doped type opposite to the first doped type; and
forming a first electrode on the heavily-doped region in the first surface of the substrate.

2. The method of fabricating the solar cell according to claim 1, wherein the substrate has the second doped type.

3. The method of fabricating the solar cell according to claim 1, wherein the step of partially removing the portion of the first doped region exposed by the patterned mask layer and the portion of the dopant in the first doped region exposed by the patterned mask layer includes performing a dry etching process.

4. The method of fabricating the solar cell according to claim 1, further comprising forming an anti-reflection layer on the first surface of the substrate before the step of forming the first electrode.

5. The method of fabricating the solar cell according to claim 1, wherein the first electrode is formed on the first surface of the substrate by a printing process.

6. The method of fabricating the solar cell according to claim 4, further comprising performing a sintering process to have the first electrode contact and electrically connect the heavily-doped region.

7. The method of fabricating the solar cell according to claim 6, wherein the step of forming the second doped region comprises:
forming a metallic layer on the second surface of the substrate; and
utilizing the sintering process to form a metal silicide between the metallic layer and the substrate, wherein the metal silicide is the second doped region.

8. The method of fabricating the solar cell according to claim 7, further comprising forming a second electrode on the metallic layer with a printing process before the sintering process; and wherein the sintering process is performed upon the second electrode and the metallic layer.

9. The method of fabricating the solar cell according to claim 1, wherein the second doped region is formed by another diffusion process.

10. The method of fabricating the solar cell according to claim 9, further comprising forming a second electrode on the second doped region.

11. The method of fabricating the solar cell according to claim 1, wherein the dopant is diffused into the substrate to form another first doped region in the substrate adjacent to the second surface when performing the diffusion process.

12. The method of fabricating the solar cell according to claim 11, further comprising a removal step after removing the pattern mask layer to eliminate the first doped region disposed in the substrate adjacent to the second surface.

13. The method of fabricating the solar cell according to claim 1, wherein the step of partially removing the portion of the first doped region and a portion of the dopant of the first doped region includes performing a dry etching process.

14. The method of fabricating the solar cell according to claim 1, wherein a doping concentration of the lightly-doped region is substantially in a range of 10¹⁸ atom/cm³ to 10¹⁹ atom/cm³.

15. The method of fabricating the solar cell according to claim 1, wherein a sheet resistance of the lightly-doped region is substantially in a range of 90 ohm/square to 120 ohm/square.
